(19) United States
(12) Patent Application Publication
(10) Pub. No.: US 2005/0283346 A1
(43) Pub. Date: Dec. 22, 2005

(54) Distributed generation modeling system and method

(76) Inventors: Harold Edward Elkins II, Dallas, TX (US); Freeman Murray Sanderford II, Murphy, TX (US)

Correspondence Address: HUNTON & WILLIAMS LLP, 1601 BRYAN STREET, ENERGY PLAZA - 30TH FLOOR, DALLAS, TX, 75201, US

(21) Appl. No.: 10/853,732

(22) Filed: May 24, 2004

(51) Int. Cl. G01R 19/30; G01R 11/63; G01R 19/165

(52) U.S. Cl. 703/4

(57) ABSTRACT

An exemplary system for analyzing and modeling electric generators for a customer is provided. The system may include a database component and processor. The database operable to maintain data identifying a generator, a generator fuel cost projection, operating parameters, a customer load profile, and an electricity cost projection for a period of time. The processor operable to calculate a projected generation cost, and to compare the projected generation cost with the electricity cost projections to provide electricity to the customer through an electric grid. A method for modeling distributed generation is also provided. The method includes determining a projected customer electric cost to provide electricity to a customer from the electric grid and determining a projected generation cost for a generator to generate electricity for the customer for the period of time to meet the customer's projected load or electric load profile.

### TECHNICAL FIELD OF THE INVENTION

This invention relates generally to the field of analyzing electric generators for use by a customer and more particularly, but not by way of limitation, to a distributed generation modeling system and method.

### BACKGROUND OF THE INVENTION

Residential and commercial electric customers ordinarily obtain electricity from the electric grid of the local electric service provider. Unfortunately, power outages on the electric grid are not uncommon and may cause a significant disruption to the customer. For this reason, the customer may obtain an alternate source of electricity, such as local, backup or emergency generator, to provide electricity in the event of a power outage from the local electric service provider.

Electric generators are available in a wide variety of models with varying levels of electric generation capacity, operational considerations and cost. The generator may be located at the customer's site and configured to provide power in the event of an outage from the retail electric provider or local electric utility.

In addition to providing a back-up supply of electricity, the generator may also provide a cost savings to the customer where the customer's cost of generating electricity is less than the cost of purchasing electricity from the electric grid. In certain instances, such as during peak electric demand periods, for example, in deregulated electric utility markets, the cost of electricity from the electric grid may vary dramatically and may justify operation of the customer's generator during certain time periods to provide the customer's electric supply. This could provide a significant cost savings to the customer.

### SUMMARY OF THE INVENTION

From the foregoing it may be appreciated that a need has arisen for a distributed generation modeling system and method to analyze the economics of potentially acquiring a generator to provide local electric power capability that may be used in conjunction with, to supplement or in lieu of electric power received from the customer's conventional electric grid. Such generation capacity may be provided through a local generator and may be referred to as distributed generation. In accordance with the present invention, a distributed generation modeling system and method are provided that substantially eliminate one or more of the disadvantages and problems outlined above.

According to one aspect, the present invention is directed to a method for modeling distributed generation for a customer that includes determining a projected customer electric cost to provide electricity to the customer from the electric grid. The method includes determining a projected generation cost for a local or specified generator to generate electricity for the customer and comparing the projected customer electric cost with the projected generation cost over a future period.

The electricity cost projection may include a projection of costs to the customer to purchase electricity from the grid. A load profile may be provided that may be based upon the customer's actual electric usage, or generic information about electric consumption for businesses, by type or otherwise, which may be used where specific information about the customer's actual or projected load profile is not readily available or determinable. By determining the electric usage profile for a customer and using the electricity cost projections, an electric usage cost for the customer may be computed.

The method may also include providing a generator fuel cost projection that includes projected costs of the fuel utilized by the generator, such as, but not limited to, natural gas, oil and diesel fuel. In certain embodiments, the generator start-up costs may also be included. This may further include fuel costs and projected maintenance costs. The method may also include providing a generator database including information on a plurality of generators including the generator operating information as well as generator capital cost information including, in certain embodiments, acquisition costs, and generator capacity data. By selecting a generator based on the customer's electricity requirements or load profile, and utilizing the generator fuel cost projections and generator operating cost data, the cost of operating the generator to provide electricity may be accurately obtained and compared with the cost of obtaining electricity from the electric grid. The present invention provides a useful method and system for readily evaluating the benefits of utilizing electric generators as compared with electricity obtained from the electric grid.

In one aspect, the generator fuel cost projections and the electricity cost projections to purchase electricity from the grid include a high projection, a likely or expected projection, and a low projection. In one aspect, these projections are computed on a periodic basis, while in other aspects the projections are provided on a daily or hourly basis over a period of five, ten, fifteen or more years. By analyzing the cost of electricity on such an interval over an extended period of time allows for a more accurate assessment of the value of employing a generator or distributed generation to the customer.

According to another aspect, the present invention provides a system for modeling the operation of a generator for a customer that includes a database component operable to maintain data identifying a generator, a generator fuel cost and operating and maintenance cost projection, a customer load profile, and an electricity cost projection. The system includes a processor operable to calculate a generation cost to generate electricity utilizing the generator based on the generator fuel cost projection, operating and maintenance cost projection, and, in certain embodiments, a start-up cost projection. The processor may be further operable to compare the generation cost with the electricity cost projection based on the customer load profile. According to one aspect, the processor is operable to determine a capacity value based on the capacity of the generator to generate electricity in a given location on the transmission grid for times other than the final dispatch for potential resale to the electric grid. According to yet another aspect, the processor may be operable to compute an environmental delta based on environmental restrictions to the final dispatch of the generator.

The present invention provides a profusion of technical advantages and other benefits that include one or more of the following. One such technical advantage of the present invention includes the capability to conveniently and easily determine an accurate assessment of the value of acquiring a generator or local generation to supplement or, in some instances, replace electricity provided through the grid.

An advantage of the present invention includes calculating a preliminary dispatch that may be obtained by determining, such as on an hourly basis, periods of time where the variable or incremental cost to generate electricity is less than the cost to purchase electricity from the grid for the customer. While yet another advantage of the present invention may include computing a dispatch, on an hourly basis, where the sum of the operating costs for operating the generator for the period combined with the actual generation costs including the fuel and start-up costs are less than the electricity costs to purchase electricity from the grid for the period.

Other technical advantages and benefits are readily apparent to one skilled in the art from the following detailed description of the invention when read in conjunction with the accompanying figures and claims.

### BRIEF DESCRIPTION OF THE DRAWINGS

For a more complete understanding of the present invention and the advantages thereof, reference is now made to the following brief description, taken in connection with the accompanying drawings and detailed description, wherein like reference numerals represent like parts in which:

FIG. 1 is a block diagram of a distributed generation modeling system according to one aspect of the present invention;

FIG. 2 is a generator data information illustrating generator information that is maintained according to one aspect of the present invention;

FIG. 3 illustrates a data file for maintaining customer or generic load profiles, according to another one aspect of the present invention;

FIG. 4 illustrates a list of generic load profiles that may be maintained for types of businesses for-use by the present invention;

FIG. 5 illustrates a data file structure, according to one aspect of the present invention, for maintaining fuel and electricity projections over specified intervals for a future period;

FIG. 6 illustrates financial assumptions useful for generating the model, according to another aspect of the present invention;

FIG. 7 illustrates miscellaneous variables and adders that may be included in the model or database of the system according to yet another aspect of the present invention;

FIG. 8 illustrates a report, according to one aspect of the present invention, of a generator modeled for a customer; and

FIG. 9 illustrates a flow chart of a method for modeling a distributed generator for a customer, according to another aspect of the present invention.

### DETAILED DESCRIPTION OF THE INVENTION

It should be understood at the outset that although an exemplary implementation of the present invention is illustrated below, the present invention may be implemented using any number of techniques, whether currently known or in existence. The present invention should in no way be limited to the exemplary implementations, drawings, and techniques illustrated below, including the exemplary design and implementation illustrated and described herein.

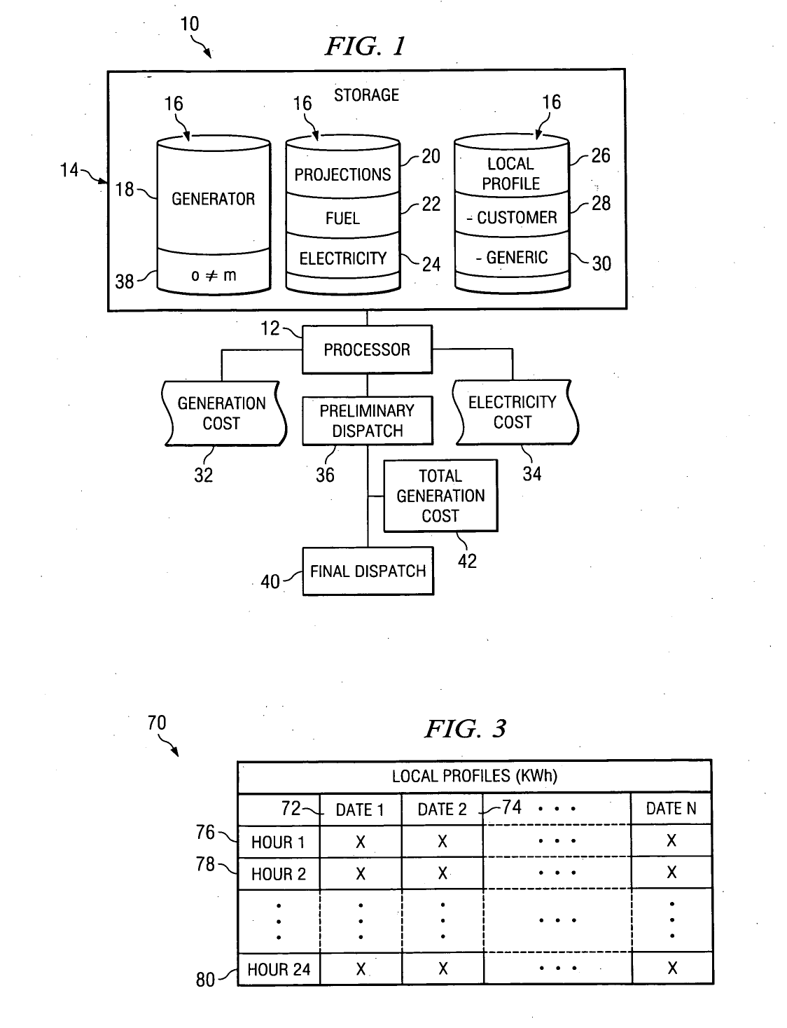

FIG. 1 illustrates one aspect of a distributed generation modeling system 10 of the present invention. The present invention is a unique system and method useful for analyzing the use of local or distributed electric generation, which may be distributed at the customer or other locations, to provide lower cost electricity at certain times. In one embodiment of the distributed generation modeling system 10, multiple generators may be modeled so that various generators may be compared to determine which generator may be the most economical to purchase and operate based on that customer's projected load profile and the projected energy prices to be provided through the electric grid.

The present invention is capable of analyzing, based on the customer's electrical needs, a variety of generators and, based on estimates of fuel and electricity prices over a future period, determining the benefits to the customer of employing a generator. This analysis may be achieved, in one embodiment, through hourly comparisons of operational and economic projections. The present invention, in one embodiment, enables a comparison of a plurality of generators, which may be referred to as distributed generators, to readily evaluate the preferable generator for the consumer, utilizing illustrative reports produced by the present invention.

According to one aspect, the distributed generation modeling system 10, which may also be referred to as the “system” 10, may be implemented on a standard computer system or other device capable of processing information and data and includes a processor 12 and a storage device 14. The storage device 14 is adapted to store one or more database components 16 operative or operable to maintain data identifying one or more generators which may be used to generate electricity for the consumer and will be analyzed for these purposes by the present invention. For example, generator variable and fixed costs may be provided that include heat rate or efficiency curves, start-up fuel costs and maintenance costs, variable and fixed maintenance costs, and even acquisition and/or financing costs.

The database components 16 are further operable to maintain data identifying projections 20 that may include estimates of future prices for commodities utilized in certain aspects of the present invention. According to one aspect, the projections data includes fuel cost projections 22 and electricity costs projections 24. The fuel cost projections 22 include information identifying fuel, such as natural gas, diesel, and/or other fuels that may be utilized to operate the one or more generators 18. The projections are based on future estimates on an hourly, daily, weekly, monthly, or other time-dependent basis of the cost of such fuels estimated over a period of time, such as five, ten, fifteen or more years. In this manner, the system 10 is provided with useful information for accurately projecting or estimating the cost to operate the generators 18 on a periodic basis at certain future times and overall potential savings and/or payback dates may be estimated to assist on determining whether to purchase, lease or finance a local generator.

The electricity cost projections 24 may include information on an hourly, daily, monthly, yearly or other interval over a future period of time, such as five, ten, fifteen or more years to purchase electricity from an electric service provider from a standard electric grid. In a deregulated electricity market, multiple electricity cost projections may be provided for various electricity providers, and such projections will likely vary depending on such factors as the time of year and the load profile or shape. According to one aspect of the present invention, the fuel cost projections 22 and electricity cost projections 24 may be generated by the user of the system 10 estimating the costs of fuel and electricity and preparing such projections, while in other aspects, the fuel and electricity cost projections 22 and 24 may be obtained from businesses, such as energy trading, commodity futures markets or other commodity businesses, which generate such information and from whom a user of the present system may obtain such projections.

The database components 16 may also maintain data identifying load profiles 26, which may also be known as load shapes, that include projected electric usage information. The load profile 26, according to one aspect of the invention, may include a customer load profile 28, generic load profiles 30, and/or a system load profile.

The customer load profile 28 includes the customer's electric usage information in kilowatt-hours or kWh for each hour, or in other aspects on a daily or other basis, over a recent period, such as the prior twelve months. The system 10 may utilize the customer load profile 28 to determine the appropriate generator or generators to select based on the capacity, capital costs and operating and maintenance costs of the generator matched with the needs of the customer. The generic load profiles 30 include electric usage in kilowatt-hours for generic types of businesses, which may be useful where a specific customer load profile 28 is not available. Thus, the customer's business type may be determined or estimated and a generic load profile 30 for a similar business may be utilized to estimate the customer's electrical usage. Because the price charged by a retail electricity provider may vary depending on such factors as the system or grid load profile, in one embodiment, a system or grid load profile, not shown on FIG. 1, may be provided as one of the database components 16.

It will be appreciated that the generator information maintained in the database component 16 may be utilized in virtually any available file format, such as a standard data file, an ASCII file, a spreadsheet or other file format that would be known to one skilled in the art. According to one aspect of the present invention, the system 10 utilizes Microsoft Excel and the database components 16 are provided as Microsoft Excel spreadsheet format.

According to one aspect, the user of the system 10 selects one or more of the generators 18 based on the customer load profile 28 or appropriate generic load profile 30. The processor 18 is operable to calculate a generation cost 32 to generate electricity for the customer utilizing the information on the selected generator 18 and the fuel cost projections 22 to fuel the generator 18. The processor 12 is further operable to generate an electricity cost 34 based on the customer load profile 28, or appropriate generic load profile 30 for the customer and the electricity cost projections 24. The processor 12 is further operable to compare the generation cost 32 with the electric cost 34 to determine the benefits to the customer of employing a generator. It is readily apparent that the present inventions is useful by a number of businesses for assisting customers in analyzing the use of generators by modeling the benefits to the customer of one or more generators using realistic information on the customer's anticipated electrical usage and future commodity price projections.

According to one aspect, the processor 12 of the present invention is further operable to determine a preliminary dispatch 36 of the modeled generator 18. The preliminary dispatch 36 identifies the intervals where the generator will be operating and providing some or all of the electricity needs of the customer, instead of the customer obtaining all of its electricity needs from the standard electric power grid. The interval may be hourly, daily, weekly, monthly, or otherwise, however it may be useful for the interval analyzed to be based on the projection intervals for the fuel cost projections 22 and/or electricity cost projections 24. The preliminary dispatch is determined by comparing the electricity cost 34, the generation cost 32 for each hour, for example, over a future period of, for example, fifteen years. In this manner, the preliminary dispatch 36 indicates, on an hour-by-hour basis, the hours where it is more efficient and/or cost effective for the customer to obtain electricity from the electric power grid or to utilize the generator 18 to generate electricity.

According to yet another aspect of the present invention, the processor is further operable to determine a final dispatch 40 of the selected generator 18 modeled for the customer. According to one aspect, the final dispatch 40 utilizes operation and maintenance information 38 for the selected generator(s) 18 to be modeled. The operation and maintenance information includes the cost on an interval basis, such as hourly, daily, or otherwise, to operate and maintain the selected generator 18 to be modeled by the present invention. The operation and maintenance information may further include variable and fixed start-up and stop costs for the selected generator 18.

The final dispatch 40 may be calculated by adding the generation cost 32 to the operation and maintenance information 38 for each hour of the preliminary dispatch 36 to obtain a total generation cost 42, which is compared with the electricity cost 34. In this manner, the final dispatch 40 may include the hours, or other intervals where the realistic and cost benefit to the customer warrants utilizing the generator 18, as opposed to obtaining the electricity from the electric grid, such as a retail electricity provider in a deregulated electricity market.

Using the final dispatch 40, the modeled operations schedule of the generator 18, including, in one embodiment, both fixed and variable generation costs, can be compared with what the customer would otherwise pay to obtain electricity from the electric grid to derive an overall benefit for utilizing the selected generator 18 over a future period of time. The customer can then readily evaluate the value, in terms of dollars and otherwise, for purchasing and installing the selected generator 18. According to one aspect, the system 10 is operable to analyze or model a plurality of generators 18, similar to the manner described above, so that a plurality of generators 18 may be readily evaluated to determine the generator 18 that is the most advantageous for the customer.

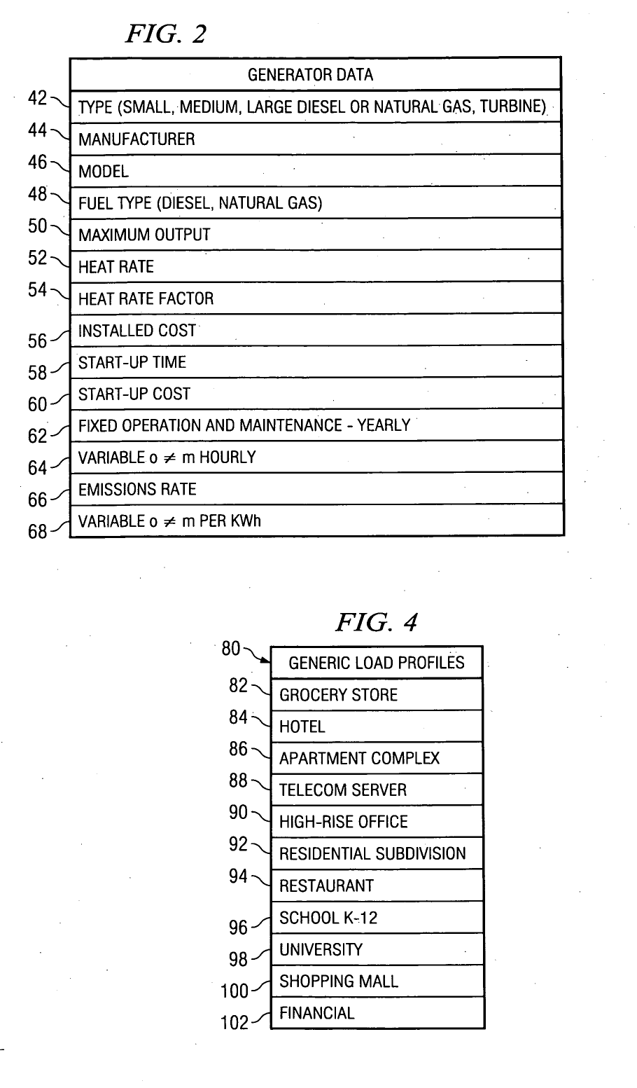

FIG. 2 illustrates one aspect of the generator 18 information that may be maintained on the plurality of generators that may be modeled by the present invention. The generator information or data may include a type of generator, such as, but not limited to, whether it is a small, medium, large diesel or natural gas type of generator, turbine or micro-turbine or other type of electric generator. Manufacturer information may be included to identify the manufacturer of the generator 18.

A model 46 information may identify a particular make or model of the generator to readily identify specific generators. A fuel type 48 information includes data such as whether the generator utilizes diesel, natural gas, oil or other types of fuel.

The generator 18 information may also include a maximum output 50 related to the electrical generation capacity, or continuous electrical output capacity of the generator. A heat rate 52 and a heat rate factor 54 information may be included to indicate, for example, but not limited to, the efficiency of the generator to convert fuel to electricity at various load or generation levels. The generator 18 information may further include an installed cost 56, which in one aspect may include the purchase price of the particular generator 18, the acquisition cost, the financing cost as well as the cost to deliver, install and ready the generator 18 for the customer. A start-up time 58 identifies the amount of time, such as in minutes, required to bring the generator online to generate electricity for the customer.

A start-up cost 60 includes information regarding the cost to start the generator and begin generating electricity. A fixed operation and maintenance 62 may include, for example, yearly operation and maintenance cost information related to operating and maintaining the generator. A variable operation and maintenance 64 includes information about the operation and maintenance cost on an interval, such as on an hourly basis or based upon the number of starts and stops of the generator.

An emissions rate 66 information provides information about the exhaust or other emissions relative to the generator 18, which may be useful for determining the appropriate generator for a particular customer, as well as particular times where the generator 18 may be able to operate. The emissions rate 66 information may be useful where the customer is situated in heavily industrialized or highly populated areas where an environmental or other emissions considerations are relevant to the selection of the generator 18.

A variable operation and maintenance per kWh 68 information is provided to identify the operation and maintenance costs of the generator per unit of electricity or power generated by the generator 18. In other aspects, additional information about the generator 18 may be provided, however the generator 18 information illustrated in FIG. 2, according to the present aspect, is an example of information that may be useful for modeling a generator for these purposes.

FIG. 3 illustrates a data structure 70 of the load profiles, on a kilowatt-hour basis, for the customer load profiles 28 and generic load profiles 30, according to one aspect of the present invention. Utilizing a standard data file or spreadsheet, information may be maintained on the electrical usage, whether prior actual usage of a customer in the case of the customer load profile 28 or generic information about customer usage based on the type of business, in the case of the generic load profile 30. Dates identify horizontal headings such as a first date 72, a second date 74, and so on for as many dates as are necessary to obtain an accurate view of the load profile for a specific customer or a generic business type. In a preferred embodiment, this information is provided on at least an hourly basis.

In one aspect, the information may be maintained on a daily basis for up to 15 years, while in other aspects more or less time may be useful. Electrical usage or load in kWh is maintained for each date, on an hour-by-hour basis, for example for a first hour 76, a second hour 78, and so on until a twenty-fourth hour 80, for each of the dates for the load profile. Although the present invention maintains information on an hourly interval, in other aspects the interval may be on a multiple or fractional portion of an hour or daily basis.

FIG. 4 illustrates an example of generic load profiles 30, which may be maintained by the system 10 based on various business types and the electrical usage typical of such businesses. For example, generic load profiles 30 may be prepared and/or maintained for typical or common businesses such as, but not limited to grocery stores 82, hotels 84, apartment complexes 86, telecom server facilities 88, high rise offices 90, residential subdivisions 92, restaurants 94, schools 96, universities 98, shopping malls 100, and financial institutions 102. It would be appreciated that in other aspects, electrical usages for other types of businesses or residential customers, such as manufacturers and retailers, may be provided and are within the spirit and scope of the present invention. The load profile 70 may store the electrical usage or load data for each associated generic load profile 30.

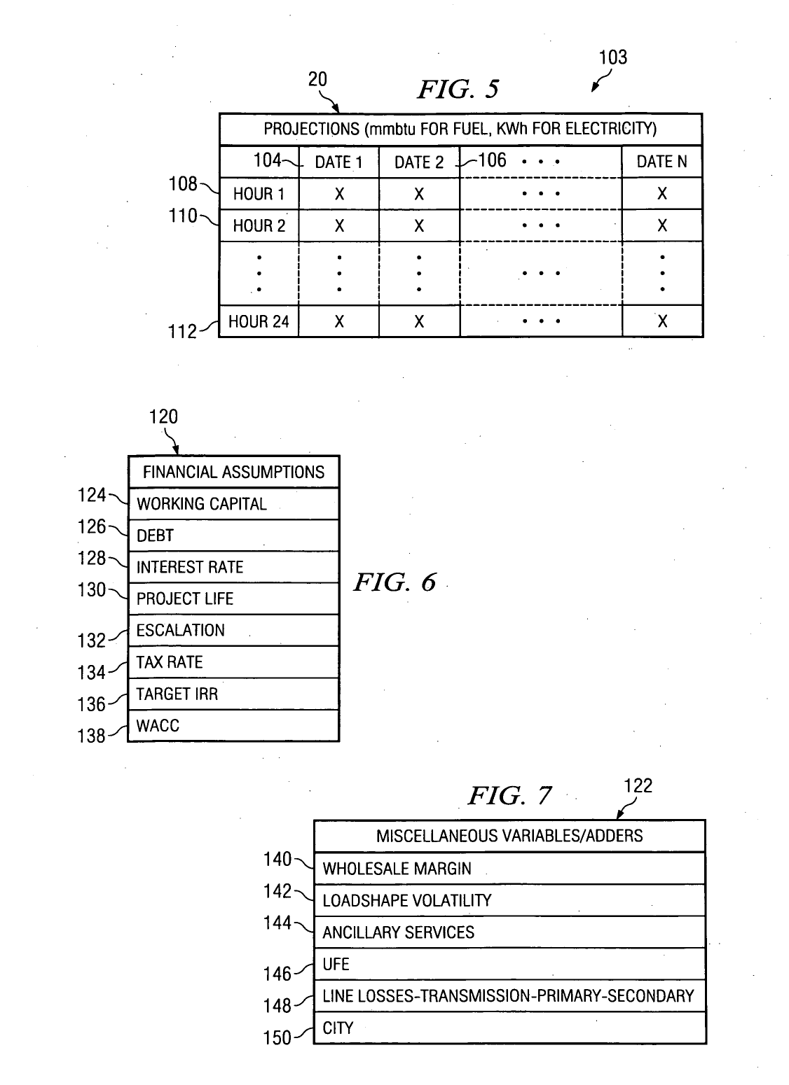

FIG. 5 illustrates a data format 103, according to one aspect, of the projections 20 which maintain information on fuel cost projections 22, such as dollars per MMBTU or million British thermal units for natural gas, and electricity cost projections 24 per kWh for electrical energy. The projections 20 information may be maintained, as previously discussed, in a number of file formats that will readily suggest themselves to one skilled in the art. In one embodiment, the information at projections 20 may be maintained in a spreadsheet format wherein the headings are provided horizontally, such as a first date 104, a second date 106, and so on to extend over a period for which the projections are desired. According to one aspect, the projections are provided for up to five years, while in other aspects they are provided for ten or fifteen years and yet in other aspects for more years.

The commodity prices may be provided on an interval basis, as previously discussed, and are illustrated on an hourly basis according to one embodiment of the invention. In this manner, a projected price for electricity or fuel is estimated for a first hour 108, a second hour 110 and so on until the twenty-fourth hour 112, for each of the dates. Thus, the projections 20 provide an hourly estimation for the cost of fuel to operate the generator, or where the projection 20 is for electricity, the cost to purchase electricity from the electric grid over, for example, a fifteen-year period is provided.

According to one aspect, an expected fuel cost projections 22 is provided substantially in the format illustrated in FIG. 5 and the electricity cost projections 24 is provided in the same or a separate file in a format substantially similar to that illustrated in FIG. 5. According to other aspects, additional projections may be useful for the fuel cost projections 22 and electricity cost projections 24, such as a high and a low projection of the fuel and electricity costs. While yet in other aspects, a plurality of projections taking into consideration various weather scenarios, geopolitical events, and a number of other scenarios that may alter the cost of fuel and electricity, may be provided to further provide the customer with an accurate estimation of the cost of electricity and fuel and the impact such changes in the fuel and electricity costs would have on the decision or benefits of utilizing a generator.

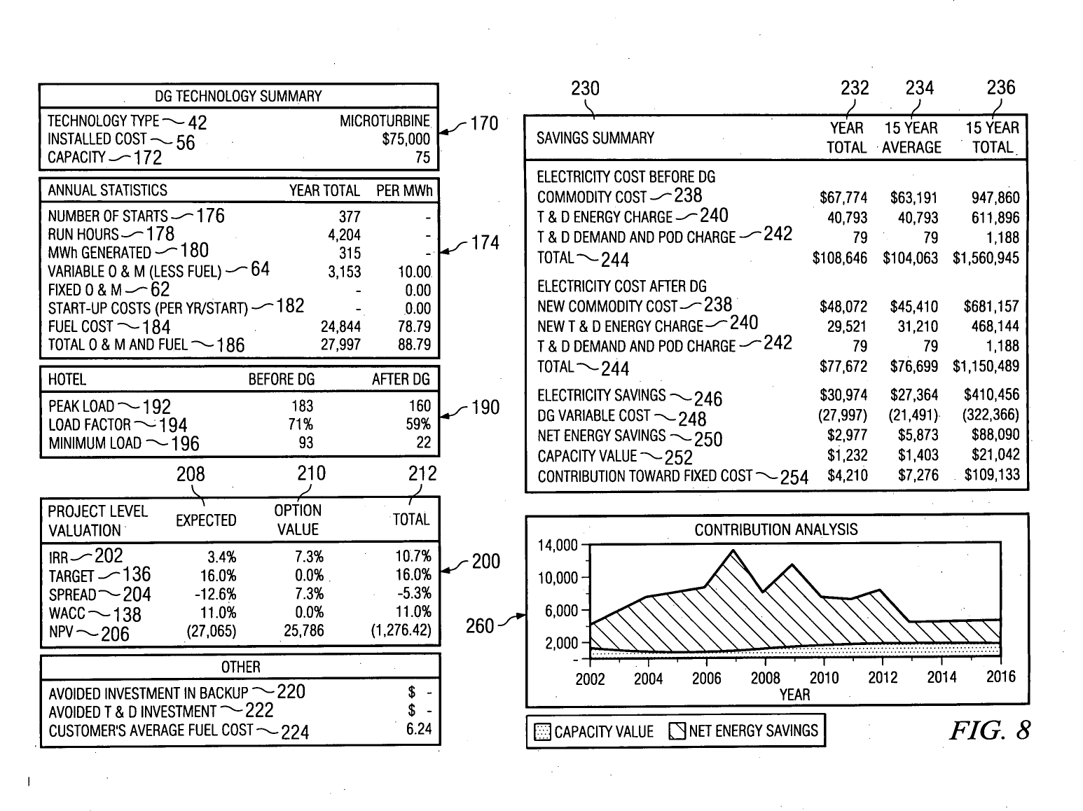

Referring to FIG. 6 and FIG. 7 and according to other aspects of the present invention, additional information may be maintained by the database components 16 such as financial assumptions 120 and miscellaneous variables and adders 122. It will be appreciated that in any financial analysis, additional financial assumptions 120 may be usefully employed, which may be stored as data files for access by the system 10. The financial assumptions 120 may include, but are not limited to, working capital 124, debt 126, and interest rate 128, such as a projected or estimated interest rate. A project life 130 estimates the useful life span of the generator 18 for analysis purposes. An escalation 132 and a tax rate 134 are also provided. The financial assumptions may also include a target initial rate of return 136 which represents a desirable return on investment for the customer. A WACC 138 maintains information on the weighted average cost of capital.

The miscellaneous variables and adders 122 may include additional factors that may alter either positively or negatively the modeling of a generator 18 by the present invention. The miscellaneous variables and adders 122 may include a wholesale margin 124, which provides information regarding the wholesale prices of electricity. A load shape volatility 142 may be provided which is related to the likelihood that the customer's electric consumption may change significantly over the modeled period. An ancillary services 144, which may project additional costs to provide electricity to the customer from the electric grid, and an un-accounted for energy (UFE) 146 may also be modeled or projected and used by System 10. A line losses 148 may be provided for analysis by the present invention to compensate for losses in electricity due to transmission line losses. Transmission and distribution costs may also be similarly utilized in implementations of the present invention. A city 150 is provided to account for metropolitan and other areas where additional charges for electricity, or other factors that may impact the model based on the location of the customer or the generator 18.

FIG. 8 illustrates one aspect of a report that may be generated by the system 10 providing information regarding a generator 18 modeled for use by a customer. The report provides a generator summary 170 that includes the distributed generator (which may be referenced as “DG”) technology type 42, the installed cost 56 and a capacity 172, which may be the electric generation capacity in kWh.

The report further includes an annual statistics 174 portion that illustrates, for example, a number of starts 176 of the generator, a run hours 178, and a megawatts generated 180 relative to operation of the generator 18 modeled for the report. The annual statistics 174 may further include the variable operation and maintenance costs 64, which may not include the fuel cost projections 22. The fixed operation and maintenance 62 may also be provided as part of the annual statistics 174 portion of the report. Additional summary information provided in this portion of the report includes a start-up cost 182 and a fuel cost 184 that were computed by the system 10 based on the model for the generator. A total operation and maintenance and fuel 186 is provided that includes the combination of the operation and maintenance for the generator, as well as the cost of fuel consumed by the generator for the modeled period of operation.

The report may provide information relative to the particular consumer, or business type where a generic load profile 30 was used. A customer summary 190 may include a peak load 192, a load factor 194, and a minimum load 196 relative to the customer's electricity usage as projected before and after implementation of the generator 18.

A projected level valuation 200 portion of the report may include information regarding an initial rate of return 202. The initial rate of return 202 is computed by the system based on the cost of the generator and the savings to the customer by utilizing the generator, compared with obtaining all the customer's electricity from the electric grid or other sources. The initial rate of return 202 may be compared with the target 136 provided in the financial assumptions 120 (see FIG. 6). A spread 204 may be provided to indicate the difference between the actual initial rate of return 202 and the targeted rate of return 136, as another means of comparing the value of utilizing the generator 18. The WACC 138 and a net present value 206 are also computed for analysis based on an investment in the generator and the expected benefits.

One advantage of the present invention provided in certain embodiments is that the project level valuation 200 portion of the report is provided with an expected value 208, an option value 210 and a total value 212 columns for comparison of various scenarios. Specifically, the expected value 208 represents an expected scenario utilizing, for example, the expected fuel and electricity cost projections 22 and 24. The option value 210 may be derived from modeling the generator 18 under a plurality of electricity cost projections 24, such as under a high projection scenario, a low projection scenario, and potentially under a number of other scenarios based on various projections as compared to the expected electricity cost projections 24. The customer can readily determine, in the event of unexpected swings or variations in commodity cost projections, the additional value that the customer may realize from utilizing the generator 18. The total value 112 identifies the sum of the expected 208 value to the customer and the option value 210 to the customer of utilizing the generator 18 as modeled by the system 10.

Other information that may be provided to, utilized by, or generated by the present invention include an avoided investment in backup 220. Such information allow consideration of costs that the customer was otherwise planning to spend on, for example, an emergency generator that would no longer be a contingent or planned cost for the customer by implementing the modeled generator 18. An avoided T&D investment 222 allows the system to analyze the customer's potential contribution towards the cost to add power facilities, such as lines, transformers and other electric systems connected to the electric grid to provide the customer's anticipated electricity needs, which would be unnecessary by employing the generator 18. The report also provides for computation of a customer's average fuel cost 224.

The report also provides a savings summary 230 that provides a summary of electricity costs before and after implementation of the distributed generator 18 over a year total 232, a fifteen year average 234, as well as a fifteen year total 236, where the modeled period was fifteen years, as in the present aspect. The savings summary 230 portion of the report includes a commodity cost 238 identifying the electricity purchased by the customer, a transmission and distribution energy charge 240 and a transmission and distribution demand and point of demand charge 242. A total 244 summarizes these costs to the customer on a before and after implementation of the generator 18 modeled by the present invention.

The report, according to one aspect, further provides for computation of an electricity savings 246 based on utilizing the generator, a variable cost 248 associated with the generator 18 and a net energy savings 250 to the customer by utilizing the generator 18. The report further provides for analysis of a capacity value 252 which may be computed, according to one aspect, by determining under certain electricity cost projection 24 scenarios instances where the customer may employ the generator 18 to sell electricity back to the power grid and derive a value from the sale of this generated electricity, net of the customer's cost to generate the electricity. The report further provides for a contribution toward fixed costs 254 that summarizes the total benefits for utilizing the generator to pay for the investment of the modeled generator 18.

The report may further include a contribution analysis 260 portion that is a graphic illustration, in the present aspect, or otherwise illustrates the electricity provided to the customer by the generator over the modeled period as a portion of the customer's total electricity consumption.

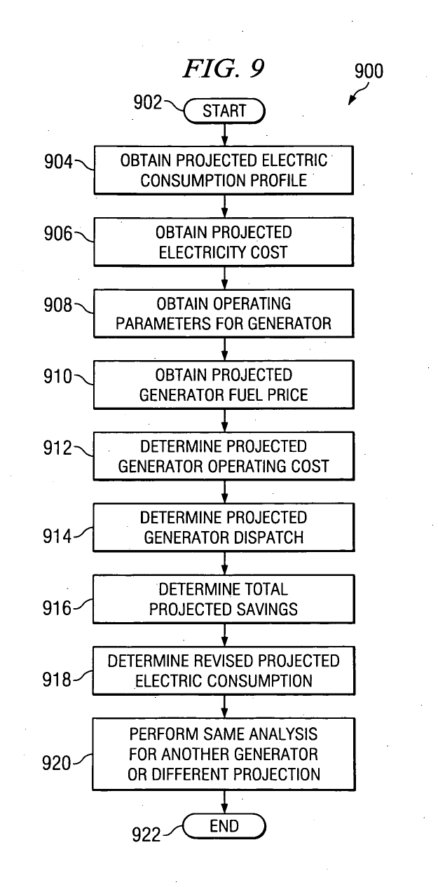

FIG. 9 is a flow chart that illustrates an exemplary method 900 for modeling distributed generation for a customer. The method 900 begins at 902 and proceeds to block 904. At block 904, a projected electric consumption profile, which may also be referred to as a projected load shape, for a customer is obtained. The projected electric consumption profile will, preferably, indicate the level of electrical demand for a period of time. The period of time will generally be divided into a plurality of smaller time periods, such as a day or hour. For example, but not by way of limitation, each period of time of the plurality of time periods may be an hour, and the period of time may extend over a period of years, such as fifteen years or for the expected life of a distributed generator that a customer is contemplating using. Of course, any of a variety of periods of time may be utilized with the present invention, and any of a variety of time periods may be used as part of the plurality of time periods for the period of time.

The projected electric consumption profile for load shape may be obtained from any of a variety of sources. For example, the projected electric consumption profile may be based upon historical electrical usage of the customer, based upon the type of business of the customer, based upon seasonal load profiles, or any of a variety of other available projected electric consumption profiles. The method 900 may also include selecting or utilizing the method 900 based upon various or different load profiles. For example, a high, medium, low, and expected projected electric consumption profile may be used to obtain more detailed information when performing such analysis.

The method 900 proceeds next to block 906 where a projected electricity cost is obtained for the period of time. The projected electricity cost projects the cost of electricity purchased from an electric provider, such as a retail electric provider in a deregulated market, for the period of time under consideration. The projected electricity cost may be provided in such a manner that the plurality of time periods referenced above in block 904 in connection with the electric consumption profile may also be associated with one or more of the plurality of time periods. The projected electricity cost may be estimated or associated with the plurality of time periods.

The projected electricity costs, similar to the projected electric consumption profile, may also be provided with various projections. For example, in a regulated electric utility environment, a high rate, medium rate, and low rate may be used to provide more detailed information when performing the analysis of method 900. Similarly, estimated or projected electricity costs from various retail electric providers in a deregulated market may also be provided so that numerous analysis can be performed.

The method block 900 proceeds next to block 908 where any of a variety of operating parameters for one or more generators are provided. In a preferred embodiment, the operating parameters may include, for example, the maximum electrical capacity or power output of the generator, and the efficiency or heat rate of the generator. In a preferred embodiment, a heat rate curve is provided for the generator to determine its efficiency at various output levels.

Other operating parameters may include operations and maintenance expenses, start-up costs, such as start-up fuel costs, installation costs, fuel type, and any of a variety of known or available operating parameters. In certain implementations, acquisition costs may be considered generator operating parameters. Acquisition costs may also include, for example, the cost of a generator, the financing costs of a generator, installation costs, etc.

The method 900 proceeds next to block 910 where a projected generator fuel price is obtained. The projected generator fuel price may be based on one or more fuels that may be used by the generator being modeled. The projected generator fuel price will preferably be provided for the entire period of time and may be associated with the plurality of time periods similar to the projected electric consumption and the projected electricity cost. A generator, such as one being used as a distributed generator, may be provided to operate on any of a variety of different fuel types. Some generators may include the ability to operate from dual or multiple fuel sources. Typical fuel types include natural gas, fuel oil, diesel, gasoline, and various other available or known petroleum or other fuel types.

Proceeding next to block 912, a projected generator operating cost to generate electricity using a selected or desired generator is determined. The projected generator operating cost may be determined based on the projected electric consumption profile for the plurality of time periods of the period of time. The projected generator operating cost is also determined based on one or more of the generator operating parameters discussed previously along with the projected fuel price of the fuel that may be used by the generator. The operating parameters, in a preferred embodiment, will include the generator capacity or maximum output and the efficiency or heat rate information associated with the generator.

Proceeding next to block 914, a projected dispatch of the generator is determined. This is done for the plurality of time periods of the period of time by comparing the projected generator operating cost, as determined in block 912, to the projected electricity cost of electricity purchased from an electric provider for the corresponding plurality of time periods. For example, a comparison may be made each hour or other time period between the projected generator operating cost and the projected electricity cost for purchasing electricity from the grid. If the projected generator operating cost is less than the projected electricity cost from the grid, the projected generator will be dispatched at a level that is equal to the projected electric consumption for that particular time period. In the event that the projected electric consumption profile for the particular time period is more than the maximum generator output, the generator may be dispatched to its maximum level and the remaining electricity needed to meet the load may be obtained through the grid. In other embodiments, a generator may have a heat rate curve such that it is most efficient at a particular output level that is not the maximum output level. This more efficient output level may be chosen as the dispatch level to satisfy economic considerations while remaining electric power needs are purchased from the electric grid.

In certain situations, even though the projected generator operating cost for a time period may be less than the projected electricity cost of electricity purchased from an electric provider through the grid, when the start-up cost of the generator is considered, it may be uneconomical to start the generator for only a short duration. In such a case, the proper decision of the method 900 may involve not starting a generator and instead choosing to purchase electricity through the grid.

In other implementations of method 900, block 914 may also include determining a second projected generator dispatch by using a second generator fuel price from block 910 and various second generator operating parameters from block 908 to determine a projected generator operating costs at block 912. At block 914, the second generator may be dispatched and, at a later stage of method 900, compared to the dispatch and economic analysis of the first generator. Of course, any number of different generators may be analyzed using the method 900.

At block 916, a total projected savings may be determined. This may include comparing a total projected cost for purchasing all electricity to meet the electric consumption profile of the customer from the electric provider or grid for the period of time to a total projected cost for dispatching a generator and purchasing any other electricity, if necessary, to meet the selected electric consumption profile of the customer for the period of time. Assuming that projected savings are predicted, at some period in the future it may be projected when the projected savings would exceed the acquisition costs of the generator. This should occur, of course, hopefully before the generator reaches its life expectancy. Comparisons may also be made to determine which one of a plurality of generators will be the first to have its projected savings exceed its acquisition costs. It should be noted that method 900 may be used to analyze any of a variety of different generators such that savings comparisons may be made from one distributed generator to another distributed generator.

Proceeding next to block 918, a revised projected electric consumption profile may be determined in certain implementations of the present invention. For example, once the projected dispatch of the generator has been projected, the remaining electricity used to meet the projected electric consumption profile for the customer may be assumed to be provided through the grid by an electric provider. This projected revised consumption profile may then be “shopped” to any of a variety of electric providers in a deregulated electricity market. This new profile may be such that electric providers may be able to more economically price this energy, resulting in further potential savings to the customer. This could also be used in one embodiment to demonstrate the customer's ability to adjust consumption patterns to qualify for reduced rates such as time-of-use or interruptable rates offered by traditional regulated utilities. The total projected savings determined at block 916 may include the additional savings that may be realized by requoting or shopping the revised consumption profile to one or more electric providers. This should result in additional savings.

Proceeding to block 920, the method 900 may include any of a variety of other or additional analysis. For example, as mentioned above, the method just described may be performed for any of a variety of different generators to determine which generator may be the most advantageous to purchase for a particular customer. Further, the method 900 may be pursued using a range of different projections such as a range of projected electric consumption profiles, projected electricity costs, and projected fuel costs.

During certain time periods the generator may be dispatched at a level less than its maximum output capacity. This results in opportunities to sell power back to the grid or, in a deregulated environment, to a third party using the grid to transport the power to the third party. The method 900 may be used in certain implementations to determine the projected available excess capacity and the cost to sell such excess capacity. In certain implementations, a projected charge to transport the power to the third party may be included as part of the method 900. The projected operating costs to generate the projected available excess capacity will, of course, take into account the projected generator fuel price, generator heat rate information and other operating parameters as needed. This available excess capacity may further justify the decision to purchase a generator and to operate using a distributed generator. The method 900 ends at 922.

Although the preferred embodiment has been described in detail, it should be understood that various changes, substitutions, and alterations can be made herein without departing from the scope of the present invention, even if all of the advantages identified above are not present. For example, the various embodiments shown in the drawings herein illustrate that the present invention may be implemented and embodied in a variety of different ways that still fall within the scope of the present invention.

Although the techniques, designs, elements, and methods described are illustrated in the embodiments as discrete or separate, these may be combined or integrated with other techniques, designs, elements, or methods without departing from the scope of the present invention. Other examples of changes, substitutions, and alterations are readily ascertainable by one skilled in the art and could be made without departing from the spirit and scope of the present invention.

1. A method for modeling distributed generation for a customer, comprising:
obtaining a projected electric consumption profile for the customer for a period of time that is divided into a plurality of time periods;
obtaining a projected electricity cost that projects the cost of electricity purchased from an electric provider for the period of time, the projected electricity cost may be associated with the plurality of time periods;
obtaining operating parameters for one or more generators, the operating parameters including an electrical generator capacity and heat rate information;
obtaining a projected fuel price for one or more fuels that may be used by the one or more generators for the period of time;
determining a projected generator operating cost to generate electricity using a generator from the one or more generators based on the projected electric consumption profile for the plurality of time periods of the period of time, the projected generator operating cost determined using at least the operating parameters associated with the generator and the projected fuel price of the fuel that may be used by the generator;
determining a projected dispatch of the generator by comparing, for the plurality of time periods, the projected generator operating cost of the generator to the projected electricity cost of electricity purchased from an electric provider for the plurality of time periods of the period of time; and
determining a revised projected electric consumption profile for the customer by subtracting the projected dispatch of the generator for the plurality of time periods from the projected electric consumption profile.

2. The method of claim 1, further comprising:
obtaining a revised projected electricity cost that projects the cost of electricity purchased from the electric provider based at least in part on the revised projected electric consumption profile for the customer.

3. The method of claim 1, further comprising:
obtaining a revised projected electricity cost that projects the cost of electricity purchased from a third party electric provider based at least in part on the revised projected electric consumption profile for the customer.

4. The method of claim 1, further comprising:
determining a second projected generator operating cost to generate electricity using a second generator selected from the one or more generators based on the projected electric consumption profile for the plurality of time periods of the period of time, the second projected generator operating cost determined using operating parameters associated with the second generator and a projected fuel price of the fuel that may be used by the second generator; and
determining a projected dispatch of the second generator by comparing, for the plurality of time periods, the second projected generator operating cost of the second generator to the projected electricity cost of electricity purchased from an electric provider for the plurality of time periods of the period of time.

5. The method of claim 1, further comprising:
determining projected available excess capacity of the generator by determining when the projected dispatch of the generator is less than the electrical generator capacity of the generator for the plurality of time periods of the period of time;
determining a projected operating cost to generate the projected available excess capacity of the generator for the plurality of time periods; and
offering to sell the projected available excess capacity to a third party at a price greater than the projected operating cost to generate the projected available excess capacity.

6. The method of claim 5, wherein the offering to sell the projected available excess capacity to the third party includes offering to sell the projected available excess capacity at a price greater than both the projected operating cost to generate the projected available excess capacity and a charge to transport the power to the third party.

7. The method of claim 1, wherein the period of time is an estimated life of the generator.

8. The method of claim 1, wherein the period of time is greater than or equal to at least ten years.

9. The method of claim 1, wherein the period of time is greater than or equal to five years.

10. The method of claim 1, wherein a time period of the plurality of time periods is an hour.

11. The method of claim 10, wherein the period of time is greater than or equal to five years, and wherein the determining a projected dispatch of the generator includes comparing the projected generator operating cost of the generator to the projected electricity cost of electricity purchased from an electric provider for each hour for five or more years in the future.

12. The method of claim 1, wherein a time period of the plurality of time periods is greater than one hour.

13. The method of claim 1, wherein a time period of the plurality of time periods is equal to or less than one hour.

14. The method of claim 1, wherein obtaining a projected electric consumption profile for the customer includes using historical consumption information.

15. The method of claim 1, wherein obtaining a projected electric consumption profile for the customer includes using a seasonal load profile.

16. The method of claim 1, wherein obtaining a projected electric consumption profile for the customer includes using a load profile based on a customer type load profile.

17. The method of claim 1, wherein obtaining a projected electric consumption profile comprises:
providing a plurality of business load profiles based on an electric consumption of a type of business;
identifying the type of business of the customer; and
selecting one of the plurality of business load profiles based on the type of business of the customer.

18. The method of claim 1, wherein obtaining a projected electricity cost that projects the cost of electricity purchased from an electric provider for the plurality of time periods further includes providing a high projected electricity cost and a low projected electricity cost.

19. The method of claim 1, wherein obtaining a projected fuel price further includes providing a high projected fuel price and a low projected fuel price.

20. The method of claim 1, wherein the projected fuel for one of the one or more fuels is natural gas.

21. The method of claim 1, wherein the projected fuel for one of the one or more fuels is oil.

22. The method of claim 1, wherein the projected fuel for one of the one or more fuels is diesel.

23. The method of claim 1, wherein the operating parameters for one or more generators further includes a generator startup cost.

24. The method of claim 1, wherein the operating parameters for one or more generators further includes a generator maintenance cost.

25. The method of claim 1, wherein the operating parameters for one or more generators further includes a generator acquisition cost to purchase a generator.

26. The method of claim 1, wherein the generator acquisition cost includes an installation cost.

27. The method of claim 1, wherein the operating parameters for one or more generators further includes a generator fuel type.

28. The method of claim 1, further comprising:
determining a total projected savings for the period of time by comparing a total projected cost for purchasing all electricity to meet the electric consumption profile of the customer from the electric provider for the period of time to a total projected cost for both dispatching the generator and purchasing electricity to meet the electric consumption profile of the customer for the period of time.

29. The method of claim 28, further comprising:
determining if the total projected savings exceeds the acquisition costs of the generator.

30. The method of claim 28, further comprising:
determining when the total projected savings exceeds the acquisition costs of the generator during the period of time.

31. The method of claim 30, wherein the acquisition costs include the capital cost, financing cost, and installation cost of the generator.

32. The method of claim 4, further comprising:
determining a first total projected savings for the period of time by comparing a total projected cost for purchasing all electricity to meet the electric consumption profile of the customer from the electric provider for the period of time to a total projected cost for both dispatching the first generator and purchasing remaining electricity to meet the electric consumption profile of the customer for the period of time; and
determining a second total projected savings for the period of time by comparing a total projected cost for purchasing all electricity to meet the electric consumption profile of the customer from the electric provider for the period of time to a total projected cost for both dispatching the second generator and purchasing remaining electricity to meet the electric consumption profile of the customer for the period of time.

33. The method of claim 32, further comprising:
determining if the first total projected savings exceeds the acquisition costs of the first generator; and
determining if the second total projected savings exceeds the acquisition costs of the second generator.

34. The method of claim 32, further comprising:
determining when the first total projected savings exceeds the acquisition costs of the first generator during the period of time; and
determining when the second total projected savings exceeds the acquisition costs of the second generator during the period of time.

35. A method for modeling distributed generation for a customer, comprising:
obtaining a projected electric consumption profile for the customer for a period of time that is divided into a plurality of time periods;
obtaining a projected electricity cost that projects the cost of electricity purchased from an electric provider for the period of time, the projected electricity cost may be associated with the plurality of time periods;
obtaining operating parameters for a first generator, the operating parameters including an electrical generator capacity and heat rate information;
obtaining a projected fuel price for one or more fuels that may be used by the first generator for the period of time;
determining a first projected generator operating cost to generate electricity using the first generator based on the projected electric consumption profile for the plurality of time periods of the period of time, the first projected generator operating cost determined using at least the operating parameters associated with the first generator and the projected fuel price of the fuel that may be used by the first generator;
determining a projected dispatch of the first generator by comparing, for the plurality of time periods, the projected first generator operating cost of the first generator to the projected electricity cost of electricity purchased from an electric provider for the plurality of time periods of the period of time;
obtaining operating parameters for a second generator, the operating parameters including an electrical generator capacity and heat rate information;
obtaining a projected fuel price for one or more fuels that may be used by the second generator for the period of time;
determining a second projected generator operating cost to generate electricity using the second generator based on the projected electric consumption profile for the plurality of time periods of the period of time, the second projected generator operating cost determined using at least the operating parameters associated with the second generator and the projected fuel price of the fuel that may be used by the second generator; and
determining a projected dispatch of the second generator by comparing, for the plurality of time periods, the projected second generator operating cost of the second generator to the projected electricity cost of electricity purchased from an electric provider for the plurality of time periods of the period of time.

36. The method of claim 35, further comprising:
determining projected available excess capacity of the first generator by determining when the projected dispatch of the first generator is less than the electrical generator capacity of the generator for the plurality of time periods of the period of time;
determining a projected operating cost to generate the projected available excess capacity of the first generator for the plurality of time periods; and
offering to sell the projected available excess capacity of the first generator to a third party at a price greater than the projected operating cost to generate the projected available excess capacity of the first generator.

37. The method of claim 35, further comprising:
determining a first total projected savings for the period of time by comparing a total projected cost for purchasing all electricity to meet the electric consumption profile of the customer from the electric provider for the period of time to a total projected cost for both dispatching the first generator and purchasing remaining electricity needed to meet the electric consumption profile of the customer for the period of time; and
determining a second total projected savings for the period of time by comparing a total projected cost for purchasing all electricity to meet the electric consumption profile of the customer from the electric provider for the period of time to a total projected cost for both dispatching the second generator and purchasing remaining electricity needed to meet the electric consumption profile of the customer for the period of time.

38. The method of claim 37, further comprising:
determining if the first total projected savings exceeds the acquisition costs of the first generator; and
determining if the second total projected savings exceeds the acquisition costs of the second generator.

39. The method of claim 37, further comprising:
determining when the first total projected savings exceeds the acquisition costs of the first generator during the period of time; and
determining when the second total projected savings exceeds the acquisition costs of the second generator during the period of time.

40. A system for modeling distributed generation for a customer, the system comprising:
a database component operable to maintain data identifying a generator, operating parameters of the generator, a generator fuel cost projection for a period of time that is divided into a plurality of time periods, a customer load profile for the period of time, and an electricity cost projection to meet the customer load profile for the period of time through electricity provided through an electric grid; and
a processor operable to calculate a projected generation cost to generate electricity for the plurality of time periods of the period of time utilizing the generator to meet the customer load profile based on the generator fuel cost projection and the operating parameters of the generator, the processor further operable to compare the projected generation cost for the plurality of time periods with the electricity cost projection to meet the customer load profile for the corresponding plurality of time periods.

41. The system of claim 40, wherein the generator fuel cost projection is based upon daily market fuel projections for fuel of a type employed by the generator, and wherein the electricity cost projection is based upon daily market electricity projections for electricity provided through the electric grid.

42. The system of claim 40, wherein the generator fuel cost projection is provided as hourly market fuel projections for fuel of a type employed by the generator, and wherein the electricity cost projection is provided as hourly market electricity projections for electricity provided through the electric grid.

43. The system of claim 42, wherein the generator fuel cost projection and electricity cost projection are projected over a period of years.

44. The system of claim 43, wherein the period of years is further defined as equal to or greater than 15 years.

45. The system of claim 40, wherein the operating parameters include an electrical generator capacity and generator heat rate information.
